(19) United States
(12) Patent Application Publication
(10) Pub. No.: US 2016/0233209 A1
(43) Pub. Date: Aug. 11, 2016

(54) SEMICONDUCTOR DEVICE

(71) Applicant: SHARP KABUSHIKI KAISHA, Osaka (JP)

(72) Inventors: Kohsuke INNAMI, Osaka-shi (JP); Nobuaki TERAGUCHI, Osaka-shi (JP)

(73) Assignee: SHARP KABUSHIKI KAISHA, Osaka-shi, Osaka (JP)

(21) Appl. No.: 15/026,546

(22) PCT Filed: Nov. 5, 2014
(86) PCT No.: PCT/JP2014/079310

§ 371 Date: Mar. 31, 2016

(30) Foreign Application Priority Data
Nov. 26, 2013 (JP) 2013-244133

(51) Int. Cl. H01L 27/02; H01L 29/205; H01L 29/20

(52) U.S. Cl. CPC H01L 27/0281; H01L 29/2003; H01L 29/205; H01L 27/0288; H01L 27/0255

(57) ABSTRACT

A semiconductor device includes a first transistor of a normally-off type, a second transistor of a normally-on type, and a third transistor of a normally-on type. The first transistor and the second transistor are connected to each other in cascode. The third transistor is connected in parallel with the second transistor. Each of the second transistor and the third transistor has an off-state breakdown voltage higher than an off-state breakdown voltage of the first transistor. The third transistor has a turn-on time shorter than a turn-on time of the second transistor.

### TECHNICAL FIELD

The present invention relates to a semiconductor device including a normally-off type transistor (enhancement-mode transistor) and a normally-on type transistor (depletion-mode transistor) connected in cascode, and particularly to a semiconductor device having an overvoltage protection function.

### BACKGROUND ART

In a semiconductor device having an overvoltage protection function, in order to protect the semiconductor device from an overvoltage caused by electrostatic discharge (ESD) or the like, configurations of transistors included in a semiconductor device have been devised and improved in such a manner as to be capable of withstanding the overvoltage, or a semiconductor device has been devised in such a manner as to include an overvoltage protection circuit.

Now, application of ESD pulses to a semiconductor device will be described. If an object (e.g., human body or conveying device) that is placed outside the semiconductor device and charged with high-voltage static electricity contacts the semiconductor device, the static electricity flows into the semiconductor device. For example, a human body model that models the application of ESD pulses to a semiconductor device as a result of a contact between a charged human body and the semiconductor device demonstrates that the rise time for a discharge current applied to the semiconductor device to reach its peak, which is about a few amperes, is 10 nsec. If the semiconductor device is in an off-state, when the discharge current flows from a power source terminal of the semiconductor device, an electrical charge accumulates at the power source terminal. Accordingly, the potential at the power source terminal rises suddenly, and an overvoltage of about 2 kV is instantaneously applied to the power source terminal.

According to PTL 1, in a semiconductor device including a normally-on type hetero-junction field-effect transistor having a high breakdown voltage and a normally-off type insulated-gate field-effect transistor that are formed in a monolithic configuration and connected in cascode, the normally-off type insulated-gate field-effect transistor is connected in parallel with an avalanche diode. Accordingly, the normally-off type insulated-gate field-effect transistor is prevented from breakdown that may result from the application of a high voltage to the normally-off type insulated-gate field-effect transistor.

### CITATION LIST

### Patent Literature

PTL 1: Japanese Unexamined Patent Application Publication No. 2006-351691

### SUMMARY OF INVENTION

### Technical Problem

However, if an overvoltage caused by ESD or the like is applied to a power source terminal of a semiconductor device in which a normally-off type transistor and a normally-on type transistor are connected in cascode, the voltage of the normally-on type transistor increases earlier than the voltage of the normally-off type transistor. Therefore, it is necessary to take measures against overvoltage applied to the normally-on type transistor.

As the measures against overvoltage applied to the normally-on type transistor, the following two measures are possible. The first measure is a method of increasing an off-state breakdown voltage of the normally-on type transistor to be higher than the voltage applied between the drain and the source (or collector and emitter) of the normally-on type transistor. The second measure is a method of turning on the normally-on type transistor before the voltage applied between the drain and the source (or collector and emitter) of the normally-on type transistor reaches an off-state breakdown voltage of the normally-on type transistor, thereby preventing the potential difference between the drain and the source (or collector and emitter) of the normally-on type transistor from becoming higher than or equal to the off-state breakdown voltage of the normally-on type transistor. Note that the term “off-state breakdown voltage of a transistor” refers to the maximum allowable drain-source voltage (maximum allowable collector-emitter voltage) during an off-state of the transistor.

Regarding the first measure, it is necessary to redesign the layout of the normally-on type transistor in order to increase the off-state breakdown voltage, and this redesign results in deterioration of characteristics such as an increase in on-resistance. In addition, the normally-on type transistor used in the cascode connection in the semiconductor device has an off-state breakdown voltage of about 1 kV, which is even lower than the voltage applied by ESD, which is about 2 kV. Accordingly, even if the off-state breakdown voltage of the normally-on type transistor is increased, if ESD pulses applied to the power source terminal of the semiconductor device are applied directly to the drain (or collector) of the normally-on type transistor, breakdown of the normally-on type transistor occurs. Therefore, the first measure is not a realistic improvement plan.

Regarding the second measure, while the normally-on type transistor used in the cascode connection in the semiconductor device as a high-power transistor (power transistor having a maximum power consumption of about 10 W or more) has a turn-on time of about 30 nsec, the rise time of a discharge current generated by ESD is about 10 nsec as described above. Accordingly, the second measure is difficult to realize as long as the normally-on type transistor is a high-power transistor. Note that the term “turn-on time of a transistor” refers to a time taken from inputting a voltage signal (or current signal) for turning on the transistor to the gate (or base) of the transistor to turning on the transistor.

Under the above circumstances, an object of the present invention is to provide a semiconductor device that includes a normally-off type transistor and a normally-on type transistor connected in cascode and that can increase a breakdown voltage with respect to overvoltage.

### Solution to Problem

In order to accomplish the above object, a semiconductor device according to the present invention has the following configuration (first configuration) including a first transistor of a normally-off type, a second transistor of a normally-on type, and a third transistor of a normally-on type. The first transistor and the second transistor are connected to each other in cascode. The third transistor is connected in parallel with the second transistor. Each of the second transistor and the third transistor has an off-state breakdown voltage higher than an off-state breakdown voltage of the first transistor. The third transistor has a turn-on time shorter than a turn-on time of the second transistor.

The first configuration of the semiconductor device may be a configuration (second configuration) further including a diode, a power source terminal, and a ground terminal. Each of the first transistor, the second transistor, and the third transistor includes a first electrode, a second electrode, and a control electrode. The power source terminal is connected to the first electrode of the second transistor and the first electrode of the third transistor. The second electrode of the second transistor and the second electrode of the third transistor are connected to the first electrode of the first transistor. The second electrode of the first transistor is connected to the ground terminal. The diode is provided between the power source terminal and the control electrode of the third transistor in such a manner that a cathode electrode of the diode is connected to the power source terminal and an anode electrode of the diode is connected to the control electrode of the third transistor. An avalanche voltage of the diode is higher than a rated voltage between the power source terminal and the ground terminal and is lower than or equal to the off-state breakdown voltage of the third transistor.

The first or second configuration of the semiconductor device may be a configuration (third configuration) in which the second transistor and the third transistor are formed by the same wafer processing.

Any one of the first to third configurations of the semiconductor device may be a configuration (fourth configuration) in which the second transistor and the third transistor are formed on a single semiconductor chip.

The fourth configuration of the semiconductor device may be a configuration (fifth configuration) in which all electrical connection paths for connecting the second transistor and the third transistor in parallel with each other are formed on the semiconductor chip.

Any one of the first to fifth configurations of the semiconductor device may be a configuration (sixth configuration) in which each of the second transistor and the third transistor is a transistor including a wide bandgap semiconductor.

The sixth configuration of the semiconductor device may be a configuration (seventh configuration) in which the transistor including the wide bandgap semiconductor is a gallium nitride (GaN)-based transistor.

### Advantageous Effects of Invention

According to the present invention, it is possible to increase a breakdown voltage with respect to overvoltage in a semiconductor device that includes a normally-off type transistor and a normally-on type transistor connected in cascode.

### BRIEF DESCRIPTION OF DRAWINGS

FIG. 1 is a diagram illustrating a configuration of a semiconductor device according to a first embodiment of the present invention.

FIG. 2 is a diagram illustrating a configuration of a semiconductor device according to a second embodiment of the present invention.

FIG. 3 is a top view illustrating a schematic structure of a semiconductor device according to a third embodiment of the present invention.

### DESCRIPTION OF EMBODIMENTS

### First Embodiment

A semiconductor device according to a first embodiment of the present invention will be described with reference to FIG. 1.

FIG. 1 is a diagram illustrating a configuration of a semiconductor device 1 according to this embodiment. The semiconductor device 1 according to this embodiment includes a normally-off type transistor Q1, normally-on type transistors Q2 and Q3, resistors R1 and R2, a ground terminal T1, a power source terminal T2, and a control terminal T3. Each of the normally-on type transistors Q2 and Q3 is a transistor that has an off-state breakdown voltage higher than that of the normally-off type transistor Q1, and the normally-on type transistor Q3 is a transistor that has a turn-on time shorter than that of the normally-on type transistor Q2. It is possible to make the turn-on time of the normally-on type transistor Q3 shorter than that of the normally-on type transistor Q2 by using the normally-on type transistor Q2 as a high-power transistor (power transistor having a maximum power consumption of about 10 W or more) and by using the normally-on type transistor Q3 as a power transistor not suitable for high-power use (power transistor having a maximum power consumption of less than about 10 W).

The normally-off type transistor Q1 is an n (negative)-channel MOSFET (Metal Oxide Semiconductor Field Effect Transistor), and each of the normally-on type transistors Q2 and Q3 is a gallium nitride (GaN)-based n-channel hetero-junction field-effect transistor.

The normally-off type transistor Q1 and the normally-on type transistor Q2 are connected in cascade and are provided between the ground terminal T1 and the power source terminal T2. That is, the ground terminal T1 is connected to the source electrode of the normally-off type transistor Q1, the drain electrode of the normally-off type transistor Q1 is connected to the source electrode of the normally-on type transistor Q2, and the drain electrode of the normally-on type transistor Q2 is connected to the power source terminal T2.

The gate electrode of the normally-off type transistor Q1 is connected to the control terminal T3, and the gate electrode of the normally-on type transistor Q2 is connected to the ground terminal T1 via the resistor R1.

Further, the normally-on type transistor Q3 is connected in parallel with the normally-on type transistor Q2. That is, the source electrode of the normally-on type transistor Q3 is connected to the source electrode of the normally-on type transistor Q2, and the drain electrode of the normally-on type transistor Q3 is connected to the drain electrode of the normally-on type transistor Q2.

The gate electrode of the normally-off type transistor Q3 is connected to the ground terminal T1 via the resistor R2.

Note that the ground terminal T1 and the source electrode of the normally-off type transistor Q1 may be formed of different conductive materials or the same conductive material. Similarly, the power source terminal T2 and each drain terminal of the normally-on type transistors Q2 and Q3 may be formed of different conductive materials or the same conductive material. Similarly, the control terminal T3 and the gate electrode of the normally-off type transistor Q1 may be formed of different conductive materials or the same conductive material.

The semiconductor device 1 having the above configuration according to this embodiment operates as follows. In the state where the ground terminal T1 is kept at a ground potential and the power source terminal T2 is supplied with a power source voltage, the semiconductor device 1 according to this embodiment performs switching operations in response to starting and stopping application of a voltage to the control terminal T3. Note that instead of switching between starting and stopping application of a voltage to the control terminal T3, the level of a voltage signal supplied to the control terminal T3 may be switched between two levels: a high level and a low level.

Upon stopping application of a voltage that has been applied to the control terminal T3, the gate-source voltage of the normally-off type transistor Q1 changes from a voltage higher than or equal to a threshold voltage to a voltage lower than the threshold voltage, and the normally-off type transistor Q1 transitions from an on-state to an off-state. This prevents a drain current of the normally-off type transistor Q1 from flowing. However, since the normally-on type transistors Q2 and Q3 are kept in an on-state, the potential between the drain electrode of the normally-off type transistor Q1 and each source electrode of the normally-on type transistors Q2 and Q3 increases. Then, the gate-source voltage of each of the normally-on type transistors Q2 and Q3 changes from a voltage higher than or equal to a threshold voltage to a voltage lower than the threshold voltage, and the normally-on type transistors Q2 and Q3 transition from an on-state to an off-state. Note that the term “threshold voltage” refers to a gate-source voltage of a transistor to turn on the transistor; the threshold voltage of a normally-off type transistor is a positive voltage, and the threshold voltage of a normally-on type transistor is a negative voltage.

Upon starting application of a voltage to the control terminal T3, which has been stopped, the gate-source voltage of the normally-off type transistor Q1 changes from a voltage lower than the threshold voltage to a voltage higher than or equal to the threshold voltage, and the normally-off type transistor Q1 transitions from an off-state to an on-state. This causes the drain current of the normally-off type transistor Q1 to start to flow. However, since the normally-on type transistors Q2 and Q3 are kept in an off-state, the potential between the drain electrode of the normally-off type transistor Q1 and each source electrode of the normally-on type transistors Q2 and Q3 decreases. Then, the gate-source voltage of each of the normally-on type transistors Q2 and Q3 changes from a voltage lower than the threshold voltage to a voltage higher than or equal to the threshold voltage, and the normally-on type transistors Q2 and Q3 transition from an off-state to an on-state.

Since the semiconductor device 1 according to this embodiment includes the normally-on type transistors Q2 and Q3 each having a high off-state breakdown voltage, breakdown does not occur even if a high voltage is applied between the power source terminal T2 and the ground terminal during an off-state of the normally-off type transistor Q1 and the normally-on type transistors Q2 and Q3. By using the normally-off type transistor Q1 as a power transistor that has a rated voltage lower than or equal to one-tenth of the rated voltage of the semiconductor device 1 according to this embodiment and that is not suitable for high-power use (power transistor having a maximum power consumption less than about 10 W), the normally-on type transistor Q2 has dominant switching characteristics and conductive characteristics. Accordingly, the semiconductor device 1 as a whole according to this embodiment can be a high-power-use semiconductor device that has advantages of the normally-on type transistor Q2, such as high breakdown voltage, favorable switching characteristics and conductive characteristics, and that performs a normally-off operation in which flow of current can be blocked between the power source terminal T2 and the ground terminal T1 in the state where a voltage is not applied to the control terminal T3.

However, in some cases, an overvoltage caused by ESD or the like that is even higher than the off-state breakdown voltages of the normally-on type transistors Q2 and Q3 may be instantaneously applied to the power source terminal T2. The semiconductor device 1 according to this embodiment takes a measure against such an overvoltage by using the normally-on type transistor Q3.

During an off-state of each of the normally-off type transistor Q1 and the normally-on type transistors Q2 and Q3, if an overvoltage is applied to the power source terminal T2, the potential at the drain electrode of the normally-on type transistor Q2 increases. In addition, current flows between the drain electrode and the gate electrode of the normally-on type transistor Q2 until the drain-gate capacitance of the normally-on type transistor Q2 is brought to a full-charge level. Then, a voltage drop occurs in the resistor R1, resulting in an increase in the potential between the gate electrode of the normally-on type transistor Q2 and the resistor R1. Once the potential between the gate electrode of the normally-on type transistor Q2 and the resistor R1 increases and the gate-source voltage of the normally-on type transistor Q2 becomes higher than or equal to the threshold voltage, the normally-on type transistor Q2 is turned on, and the potential at the drain electrode of the normally-on type transistor Q2 starts to decrease. If the configuration does not include the normally-on type transistor Q3, however, the drain-source voltage of the normally-on type transistor Q2 exceeds the off-state breakdown voltage of the normally-on type transistor Q2 before the normally-on type transistor Q2 is turned on because the normally-on type transistor Q2, which is a high-power transistor, has a long turn-on time.

The semiconductor device 1 according to this embodiment performs the above operation if an overvoltage is applied to the power source terminal T2 during an off-state of each of the normally-off type transistor Q1 and the normally-on type transistors Q2 and Q3. In addition, the potential at the drain electrode of the normally-on type transistor Q3 (corresponding to the potential at the drain electrode of the normally-on type transistor Q2) increases, and further, current flows between the drain electrode and the gate electrode of the normally-on type transistor Q3 until the drain-gate capacitance of the normally-on type transistor Q3 is brought to a full-charge level. Then, a voltage drop occurs in the resistor R2, resulting in an increase in the potential between the gate electrode of the normally-on type transistor Q3 and the resistor R2. Once the potential between the gate electrode of the normally-on type transistor Q3 and the resistor R2 increases and the gate-source voltage of the normally-on type transistor Q3 becomes higher than or equal to the threshold voltage, the normally-on type transistor Q3 is turned on, and the potential at the drain electrode of the normally-on type transistor Q3 (corresponding to the potential at the drain electrode of the normally-on type transistor Q2) starts to decrease. The potential at the drain electrode of the normally-on type transistor Q2 can be decreased before the drain-source voltage of the normally-on type transistor Q2 exceeds the off-state breakdown voltage of the normally-on type transistor Q2 because the normally-on type transistor Q3, which is not a high-power transistor, has a turn-on time shorter than that of the normally-on type transistor Q2. This prevents breakdown of the normally-on type transistor Q2 that may result from the drain-source voltage of the normally-on type transistor Q2 becoming higher than or equal to the off-state breakdown voltage of the normally-on type transistor Q2.

By turning on the normally-on type transistor Q3, the potential at the drain electrode of the normally-off type transistor Q1 in an off-state increases. Accordingly, it is desirable to also take a measure against overvoltage applied to the normally-off type transistor Q1. For example, as in PTL 1, the normally-off type transistor Q1 may be connected in parallel with an avalanche diode.

Here, it is desirable that the turn-on time of the normally-on type transistor Q3 be shorter than a time taken for the drain-source voltage of the normally-on type transistor Q2 to reach the off-state breakdown voltage of the normally-on type transistor Q2 as a result of the rise of an assumed overvoltage. This can prevent breakdown of the normally-on type transistor Q2 that may result from the application of an assumed overvoltage (e.g., ESD human body model).

However, as long as the turn-on time of the normally-on type transistor Q3 is shorter than the turn-on time of the normally-on type transistor Q2, the turn-on time of the normally-on type transistor Q3 is not limited to a time shorter than the time taken for the drain-source voltage of the normally-on type transistor Q2 to reach the off-state breakdown voltage of the normally-on type transistor Q2 as a result of the rise of an assumed overvoltage. When the turn-on time of the normally-on type transistor Q3 is shorter than the turn-on time of the normally-on type transistor Q2, breakdown of the normally-on type transistor Q2 is less likely to be caused by the application of an overvoltage than in a case where the normally-on type transistor Q3 is not provided and where the application of an overvoltage causes the normally-on type transistor Q2 to be turned on (the above-described second measure).

Although a MOSFET is used as the normally-off type transistor Q1 in this embodiment, an IGBT (Insulated Gate Bipolar Transistor) or the like may be used instead of a MOSFET. The normally-off type transistor Q1 is not limited to the above-mentioned examples of transistors as long as the normally-off type transistor Q1 is a normally-off type transistor that performs switching operations in accordance with the voltage or current applied to the control terminal T3 and that has an off-state breakdown voltage lower than that of each of the normally-on type transistors Q2 and Q3.

In addition, although a gallium nitride (GaN)-based hetero-junction field-effect transistor is used as the normally-on type transistor Q2 in this embodiment, a J-FET (Junction-Field Effect Transistor) or the like may be used instead of a gallium nitride (GaN)-based hetero-junction field-effect transistor. The normally-on type transistor Q2 is not limited to the above-mentioned examples of transistors as long as the normally-on type transistor Q2 is a normally-off type transistor having an off-state breakdown voltage higher than that of the normally-off type transistor Q1.

It is preferable to use, as the normally-on type transistor Q2, a transistor including a wide bandgap semiconductor such as gallium nitride (GaN) or silicon carbide (SiC) because a high off-state breakdown voltage is obtainable. In addition, a gallium nitride (GaN)-based transistor has a high saturation electron velocity and can operate at a high speed. Therefore, by using gallium nitride (GaN)-based transistors as the normally-on type transistors Q2 and Q3, the breakdown voltage and operation speed of the semiconductor device 1 according to this embodiment can be increased. Note that the term “wide bandgap semiconductor” refers to a semiconductor having a bandgap wider than that of silicon (Si).

Although a gallium nitride (GaN)-based hetero-junction field-effect transistor is used as the normally-on type transistor Q3 similarly to the normally-on type transistor Q2 in this embodiment, a J-FET or the like may be used instead of a gallium nitride (GaN)-based hetero-junction field-effect transistor. The normally-on type transistor Q3 is not limited to the above-mentioned examples of transistors as long as the normally-on type transistor Q3 is a normally-on type transistor that has an off-state breakdown voltage higher than that of the normally-off type transistor Q1 and that has a turn-on time shorter than that of the normally-on type transistor Q2.

In addition, although the semiconductor device 1 according to this embodiment includes the resistors R1 and R2 as electronic components other than the transistors and terminals, the resistor R1 may be omitted. The resistor R2 may also be omitted as long as the configuration secures the function of increasing the potential at the gate electrode of the normally-on type transistor Q3 in response to the application of an overvoltage to the power source terminal T2 during an off-state of each of the normally-off type transistor Q1 and the normally-on type transistors Q2 and Q3. Furthermore, a resistor other than the resistors R1 and R2, a capacitor, a diode, a wire, and the like may be included as electronic components other than the transistors and terminals. The electronic components that may be added to the semiconductor device 1 according to this embodiment are not limited to the above-mentioned examples of electronic components.

### Second Embodiment

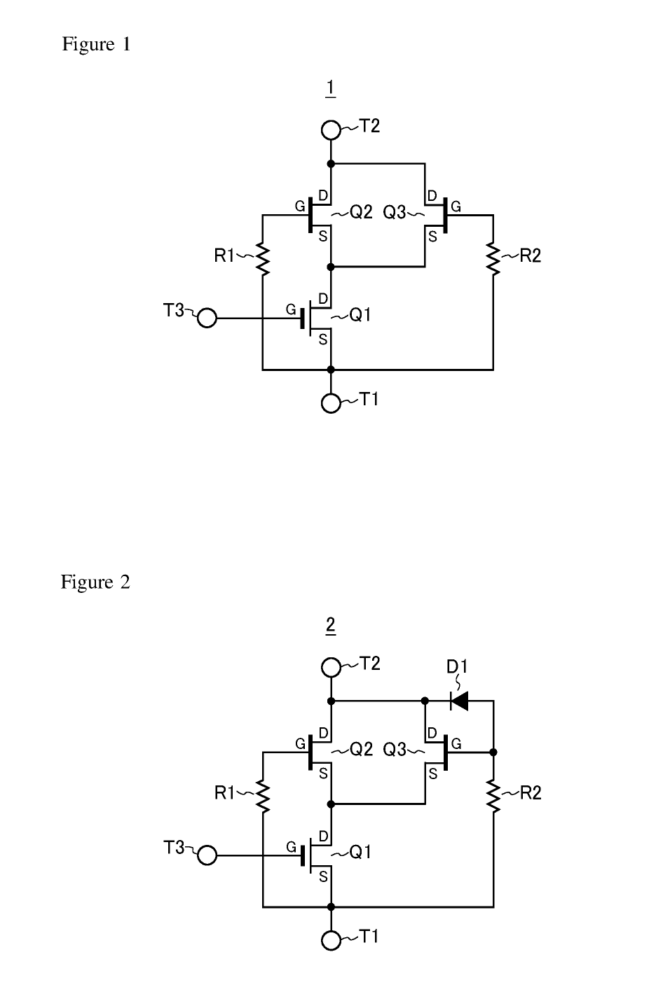

A semiconductor device according to a second embodiment of the present invention will be described with reference to FIG. 2. Note that the components in FIG. 2 that are the same as those in FIG. 1 are denoted by the same reference numerals, and description thereof will be omitted.

FIG. 2 is a diagram illustrating a configuration of a semiconductor device 2 according to this embodiment. The semiconductor device 2 according to this embodiment has a configuration obtained by adding a diode D1 to the semiconductor device 1 according to the first embodiment.

The cathode electrode of the diode D1 is connected to the power source terminal T2, and the anode electrode of the diode D1 is connected to the normally-on type transistor Q3. An avalanche voltage of the diode D1 is higher than a rated voltage of the semiconductor device 2 according to this embodiment (rated voltage between the power source terminal T2 and the ground terminal T1) and is lower than or equal to an off-state breakdown voltage of the normally-on type transistor Q3.

Note that the cathode electrode of the diode D1, the power source terminal T2, and each drain electrode of the normally-on type transistors Q2 and Q3 may be formed of different conductive materials or the same conductive material. Similarly, the anode electrode of the diode D1 and the gate electrode of the normally-on type transistor Q3 may be formed of different conductive materials or the same conductive material.

The semiconductor device 2 having the above configuration according to this embodiment operates as follows. In the state where the ground terminal T1 is kept at a ground potential and the power source terminal T2 is supplied with a power source voltage, the semiconductor device 2 according to this embodiment performs switching operations in response to starting and stopping application of a voltage to the control terminal T3.

Since the avalanche voltage of the diode D1 is higher than the rated voltage of the semiconductor device 2 according to this embodiment, in a case where the semiconductor device 2 according to this embodiment performs switching operations within the rated voltage range, current does not flow between the cathode electrode and the anode electrode of the diode D1.

Accordingly, in a case where the semiconductor device 2 according to this embodiment performs switching operations within the rated voltage range, the semiconductor device 2 according to this embodiment performs switching operations in the same manner as the semiconductor device 1 according to the first embodiment. That is, upon stopping application of a voltage that has been applied to the control terminal T3, the normally-off type transistor Q1 and the normally-on type transistors Q2 and Q3 transition from an on-state to an off-state. In addition, upon starting application of a voltage to the control terminal T3, which has been stopped, the normally-off type transistor Q1 and the normally-on type transistors Q2 and Q3 transition from an off-state to an on-state.

Similarly to the semiconductor device 1 according to the first embodiment, the semiconductor device 2 according to this embodiment includes the normally-on type transistors Q2 and Q3 each having a high off-state breakdown voltage. Accordingly, breakdown does not occur even if a high voltage is applied between the power source terminal T2 and the ground terminal during an off-state of the normally-off type transistor Q1 and the normally-on type transistors Q2 and Q3.

In addition, similarly to the semiconductor device 1 according to the first embodiment of the present invention, the semiconductor device 2 according to this embodiment takes a measure against such an overvoltage by using the normally-on type transistor Q3.

If an overvoltage is applied to the power source terminal T2, the voltage between the cathode electrode and the anode electrode of the diode D1 becomes higher than or equal to the avalanche voltage. Thus, current flows between the cathode electrode and the anode electrode of the diode D1, and the potential at the gate electrode of the normally-on type transistor Q3 increases. The increase in the potential at the gate electrode causes the normally-on type transistor Q3 to transition from an off-state to an on-state, and thus, the potential at the drain electrode of the normally-on type transistor Q2 can be decreased before the drain-source voltage of the normally-on type transistor Q2 exceeds the off-state breakdown voltage of the normally-on type transistor Q2. This prevents breakdown of the normally-on type transistor Q2 that may result from the drain-source voltage of the normally-on type transistor Q2 becoming higher than or equal to the off-state breakdown voltage of the normally-on type transistor Q2.

Note that preferable examples or modified examples described in the first embodiment can be applied to the parts of the semiconductor device 2 according to this embodiment that are the same as those of the semiconductor device 1 according to the first embodiment.

### Third Embodiment

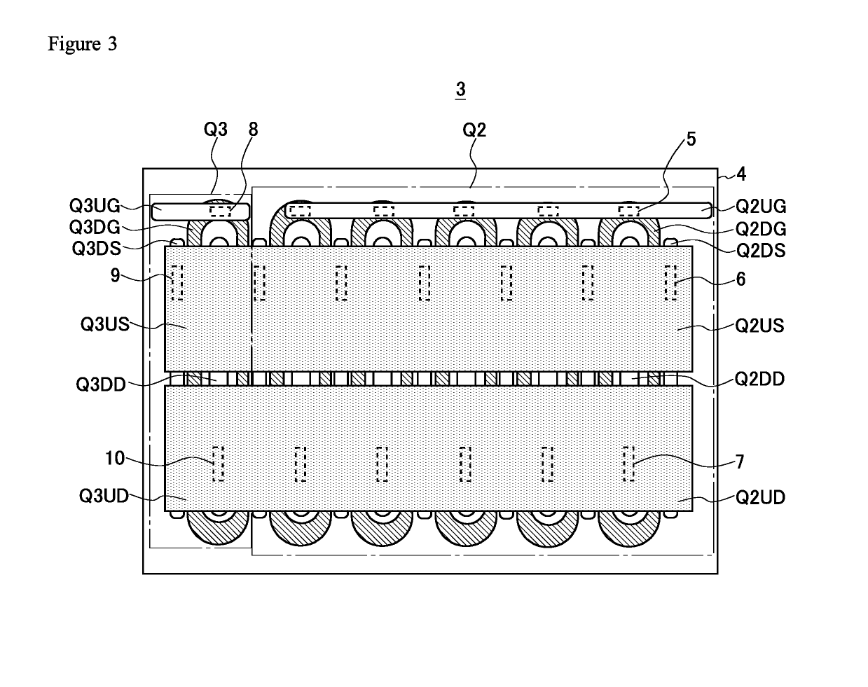

A semiconductor device according to a third embodiment of the present invention will be described with reference to FIG. 3. The semiconductor device according to the third embodiment of the present invention has the same configuration as the semiconductor device 1 according to the first embodiment illustrated in FIG. 1. Note that the components in FIG. 3 that are the same as those in FIG. 1 are denoted by the same reference numerals, and description thereof will be omitted.

FIG. 3 is a top view illustrating a schematic structure of a semiconductor device 3 according to this embodiment.

The normally-on type transistors Q2 and Q3 of the semiconductor device 3 according to this embodiment are formed by the same wafer processing.

Accordingly, the normally-on type transistors Q2 and Q3 can have substantially the same electrical characteristics. In particular, the normally-on type transistors Q2 and Q3 have substantially the same off-state breakdown voltage between the source electrode and the drain electrode, and accordingly, it is easy to adjust the timing at which the normally-on type transistor Q3 is turned on in order not to cause breakdown of the normally-on type transistor Q2. In addition, the normally-on type transistors Q2 and Q3 have substantially the same switching characteristics, and accordingly, the difference between the turn-on time of the normally-on type transistor Q2 and the turn-on time of the normally-on type transistor Q3 is easily made to correspond to the set value. Note that the term “wafer processing” refers to processing in which a unit included in a semiconductor device is formed on a semiconductor wafer substrate, and the term “same wafer processing” refers to the same kind of processing steps that are performed concurrently on the same semiconductor wafer.

Furthermore, in the semiconductor device 3 according to this embodiment, as illustrated in FIG. 3, the normally-on type transistors Q2 and Q3 are formed on a single semiconductor chip 4.

This enables arrangement of the normally-on type transistors Q2 and Q3 in the semiconductor device 3 according to this embodiment at a low cost and at a small scale. In addition, the normally-on type transistors Q2 and Q3 can be arranged side by side on the single semiconductor chip 4, and accordingly, the normally-on type transistors Q2 and Q3 can be have more substantially the same electrical characteristics.

The gate electrode of the normally-on type transistor Q2 includes a lower gate electrode Q2DG and an upper gate electrode Q2UG. A region 5 that is rectangular when viewed from above is a part in which the lower gate electrode Q2DG and the upper gate electrode Q2UG are electrically continuous and is formed between the lower gate electrode Q2DG and the upper gate electrode Q2UG in the thickness direction of the semiconductor chip 4. The source electrode of the normally-on type transistor Q2 includes a lower source electrode Q2DS and an upper source electrode Q2US. A region 6 that is rectangular when viewed from above is a part in which the lower source electrode Q2DS and the upper source electrode Q2US are electrically continuous and is formed between the lower source electrode Q2DS and the upper source electrode Q2US in the thickness direction of the semiconductor chip 4. The drain electrode of the normally-on type transistor Q2 includes a lower drain electrode Q2DD and an upper drain electrode Q2UD. A region 7 that is rectangular when viewed from above is a part in which the lower drain electrode Q2DD and the upper drain electrode Q2UD are electrically continuous and is formed between the lower drain electrode Q2DD and the upper drain electrode Q2UD in the thickness direction of the semiconductor chip 4. The gate electrode of the normally-on type transistor Q3 includes a lower gate electrode Q3DG and an upper gate electrode Q3UG. A region 8 that is rectangular when viewed from above is a part in which the lower gate electrode Q3DG and the upper gate electrode Q3UG are electrically continuous and is formed between the lower gate electrode Q3DG and the upper gate electrode Q3UG in the thickness direction of the semiconductor chip 4. The source electrode of the normally-on type transistor Q3 includes a lower source electrode Q3DS and an upper source electrode Q3US. A region 9 that is rectangular when viewed from above is a part in which the lower source electrode Q3DS and the upper source electrode Q3US are electrically continuous and is formed between the lower source electrode Q3DS and the upper source electrode Q3US in the thickness direction of the semiconductor chip 4. The drain electrode of the normally-on type transistor Q3 includes a lower drain electrode Q3DD and an upper drain electrode Q3UD. A region 10 that is rectangular when viewed from above is a part in which the lower drain electrode Q3DD and the upper drain electrode Q3UD are electrically continuous and is formed between the lower drain electrode Q3DD and the upper drain electrode Q3UD in the thickness direction of the semiconductor chip 4.

The upper source electrode Q2US of the normally-on type transistor Q2 and the upper source electrode Q3US of the normally-on type transistor Q3 are formed of the same conductive layer (same material), and the upper drain electrode Q2UD of the normally-on type transistor Q2 and the upper drain electrode Q3UD of the normally-on type transistor Q3 are formed of the same conductive layer (same material). That is, all electrical connection paths for connecting the normally-on type transistors Q2 and Q3 in parallel with each other are formed on the semiconductor chip 4.

Accordingly, the difference between the turn-on time of the normally-on type transistor Q2 and the turn-on time of the normally-on type transistor Q3 is more easily made to correspond to the set value.

### CONCLUSION

The embodiments of the present invention have been described above, but the spirit of the present invention is not limited to the embodiments, and the present invention can be implemented with various modifications without departing from the spirit of the present invention.

The above-described semiconductor device has the following configuration (first configuration) including a first transistor (Q1) of a normally-off type, a second transistor (Q2) of a normally-on type, and a third transistor (Q3) of a normally-on type. The first transistor (Q1) and the second transistor (Q2) are connected to each other in cascode. The third transistor (Q3) is connected in parallel with the second transistor (Q3). Each of the second transistor (Q2) and the third transistor (Q3) has an off-state breakdown voltage higher than an off-state breakdown voltage of the first transistor (Q1). The third transistor (Q3) has a turn-on time shorter than a turn-on time of the second transistor (Q2).

With the above configuration, upon application of an overvoltage to the semiconductor device, the third transistor can immediately transition from an off-state to an on-state, and accordingly, the potential at the connection node between the first transistor and the second transistor can be decreased before becoming excessively high. This can prevent breakdown of the second transistor that may result from the voltage applied to the second transistor becoming higher than or equal to an off-state breakdown voltage.

The first configuration of the semiconductor device may be a configuration (second configuration) further including a diode (D1), a power source terminal (T2), and a ground terminal (T1). Each of the first transistor (Q1), the second transistor (Q2), and the third transistor (Q3) includes a first electrode, a second electrode, and a control electrode. The power source terminal (T2) is connected to the first electrode of the second transistor (Q2) and the first electrode of the third transistor (Q3). The second electrode of the second transistor (Q2) and the second electrode of the third transistor (Q3) are connected to the first electrode of the first transistor (Q1). The second electrode of the first transistor (Q1) is connected to the ground terminal (T1). The diode (D1) is provided between the power source terminal (T2) and the control electrode of the third transistor (Q3) in such a manner that a cathode electrode of the diode (D1) is connected to the power source terminal (T2) and an anode electrode of the diode (D1) is connected to the control electrode of the third transistor (Q3). An avalanche voltage of the diode (D1) is higher than a rated voltage between the power source terminal (T2) and the ground terminal (T1) and is lower than or equal to the off-state breakdown voltage of the third transistor (Q3).

With the above configuration, in a case where the semiconductor device performs switching operations within the rated voltage range, current can be prevented from flowing between the cathode electrode and the anode electrode of the diode. In addition, upon application of an overvoltage to the semiconductor device, current can flow between the cathode electrode and the anode electrode of the diode, and the third transistor can automatically and immediately transition from an off-state to an on-state. Accordingly, the potential at the connection node between the first transistor and the second transistor can be decreased before becoming excessively high. This can prevent breakdown of the second transistor that may result from the voltage applied to the second transistor becoming higher than or equal to an off-state breakdown voltage.

The first or second configuration of the semiconductor device may be a configuration (third configuration) in which the second transistor (Q2) and the third transistor (Q3) are formed by the same wafer processing.

With the above configuration, the second transistor and the third transistor have substantially the same electrical characteristics, in particular substantially the same off-state breakdown voltage between the source electrode and the drain electrode, and accordingly, it is easy to adjust the timing at which the third transistor is turned on in order not to cause breakdown of the second transistor. In addition, the second transistor and the third transistor have substantially the same switching characteristics, and accordingly, the difference between the turn-on time of the second transistor and the turn-on time of the third transistor is easily made to correspond to the set value.

Any one of the first to third configurations of the semiconductor device may be a configuration (fourth configuration) in which the second transistor (Q2) and the third transistor (Q3) are formed on a single semiconductor chip.

With the above configuration, the second transistor and the third transistor can be arranged in the semiconductor device at a low cost and at a small scale. In addition, the second transistor and the third transistor can be arranged side by side on the single semiconductor chip, and accordingly, the second transistor and the third transistor can have more substantially the same electrical characteristics.

The fourth configuration of the semiconductor device may be a configuration (fifth configuration) in which all electrical connection paths for connecting the second transistor (Q2) and the third transistor (Q3) in parallel with each other are formed on the semiconductor chip.

With the above configuration, the difference between the turn-on time of the second transistor and the turn-on time of the third transistor is more easily made to correspond to the set value.

Any one of the first to fifth configurations of the semiconductor device may be a configuration (sixth configuration) in which each of the second transistor (Q2) and the third transistor (Q3) is a transistor including a wide bandgap semiconductor.

With the above configuration, since the transistor including the wide bandgap semiconductor has a high off-state breakdown voltage, each of the second transistor and the third transistor can have a high off-state breakdown voltage, and furthermore, the semiconductor device can have a high breakdown voltage.

The sixth configuration of the semiconductor device may be a configuration (seventh configuration) in which the transistor including the wide bandgap semiconductor is a gallium nitride (GaN)-based transistor.

With the above configuration, since the gallium nitride (GaN)-based transistor has a high saturation electron velocity and can operate at a high speed, the breakdown voltage and operation speed of the semiconductor device can easily be increased.

### REFERENCE SIGNS LIST

1 semiconductor device according to first embodiment
2 semiconductor device according to second embodiment
3 semiconductor device according to third embodiment
4 semiconductor chip
5 to 10 region that is rectangular when viewed from above
Q1 normally-off type transistor
Q2, Q3 normally-on type transistor
Q2DG lower gate electrode of transistor Q2
Q2UG upper gate electrode of transistor Q2
Q2DS lower source electrode of transistor Q2
Q2US upper source electrode of transistor Q2
Q2DD lower drain electrode of transistor Q2
Q2UD upper drain electrode of transistor Q2
Q3DG lower gate electrode of transistor Q3
Q3UG upper gate electrode of transistor Q3
Q3DS lower source electrode of transistor Q3
Q3US upper source electrode of transistor Q3
Q3DD lower drain electrode of transistor Q3
Q3UD upper drain electrode of transistor Q3
R1, R2 resistor
T1 ground terminal
T2 power source terminal
T3 control terminal
D1 diode

1-5. (canceled)

6. A semiconductor device comprising:
a first transistor of a normally-off type;
a second transistor of a normally-on type;
a third transistor of a normally-on type;
a diode;
a power source terminal;
a ground terminal; and
a resistor,
wherein the first transistor and the second transistor are connected to each other in cascode,
wherein the third transistor is connected in parallel with the second transistor,
wherein each of the second transistor and the third transistor has an off-state breakdown voltage higher than an off-state breakdown voltage of the first transistor, and
wherein the third transistor has a turn-on time shorter than a turn-on time of the second transistor,
wherein each of the first transistor, the second transistor, and the third transistor includes a first electrode, a second electrode, and a control electrode,
wherein the power source terminal is connected to the first electrode of the second transistor and the first electrode of the third transistor,
wherein the second electrode of the second transistor and the second electrode of the third transistor are connected to the first electrode of the first transistor,
wherein the second electrode of the first transistor is connected to the ground terminal,
wherein the diode is provided between the power source terminal and the control electrode of the third transistor in such a manner that a cathode electrode of the diode is connected to the power source terminal and an anode electrode of the diode is connected to the control electrode of the third transistor,
wherein an avalanche voltage of the diode is higher than a rated voltage between the power source terminal and the ground terminal and is lower than or equal to the off-state breakdown voltage of the third transistor, and
wherein the control electrode of the third transistor is connected to the ground terminal via the resistor.

7. The semiconductor device according to claim 6, wherein the second transistor and the third transistor are formed on a single semiconductor chip.

8. The semiconductor device according to claim 6, wherein each of the second transistor and the third transistor is a transistor including a wide bandgap semiconductor.

9. The semiconductor device according to claim 8, wherein the transistor including the wide bandgap semiconductor is a gallium nitride (GaN)-based transistor.
